(19) United States
(12) Patent Application Publication
(10) Pub. No.: US 2026/0164825 A1
(43) Pub. Date: Jun. 11, 2026

(54) IMAGE SENSOR, CAMERA COMPACT MODULE, ELECTRONIC DEVICE AND METHOD FOR MANUFACTURING PACKAGING STRUCTURE OF IMAGE SENSOR

(71) Applicants: BEIJING BOE OPTOELECTRONICS TECHNOLOGY CO., LTD., Beijing (CN); BOE TECHNOLOGY GROUP CO., LTD., Beijing (CN)

(72) Inventors: Yifeng QIN, Beijing (CN); Tonghu SUN, Beijing (CN); Fang ZHANG, Beijing (CN); Xue CAO, Beijing (CN); Feng QU, Beijing (CN); Hongxi XIAO, Beijing (CN); Liang SUN, Beijing (CN); Chuncheng CHE, Beijing (CN)

(21) Appl. No.: 18/711,075

(22) PCT Filed: May 23, 2023
(86) PCT No.: PCT/CN2023/095843

§ 371 Date: May 16, 2024

(51) Int. Cl. H10F 39/00; H10F 39/18

(52) U.S. Cl. CPC H10F 39/806; H10F 39/18

(57) ABSTRACT

The present disclosure provides an image sensor, which includes a sensor chip and a packaging structure. The packaging structure includes: a first transparent substrate; a packaging component for packaging the sensor chip, wherein the packaging component is arranged on a side of the first transparent substrate facing a photosensitive area of the sensor chip, and an orthographic projection of the packaging component on the first transparent substrate does not overlap with an orthographic projection of the photosensitive area of the sensor chip on the first transparent substrate; and a dimming component for adjusting a light intensity incident on the photosensitive area of the sensor chip, wherein the dimming component is arranged on a side of the first transparent substrate, and an orthographic projection of the dimming component on the first transparent substrate covers the orthographic projection of the photosensitive area of the sensor chip on the first transparent substrate.

### TECHNICAL FIELD

The present disclosure relates to the technical field of camera components, in particular to an image sensor, a camera compact module, an electronic device and a method for manufacturing a packaging structure of the image sensor.

### BACKGROUND

With the development of science and technology, there are more and more scenes in which cameras are applied in modern society. Such as mobile phone camera, automatic driving camera, industrial control camera, security camera, etc.

A camera compact module (CCM) is an important component of image capture and the most important part of a camera. An image sensor is the core component of the camera compact module, which converts optical signals into electrical signals and converts them into digital signals through readout circuits. CMOS image sensor (CIS) is a kind of image sensor commonly used in the camera compact module.

### SUMMARY

According to a first aspect of the present disclosure, there is provided an image sensor comprising a sensor chip and a packaging structure, wherein the packaging structure comprises: a first transparent substrate; a packaging component for packaging the sensor chip, wherein the packaging component is arranged on a side of the first transparent substrate facing a photosensitive area of the sensor chip, and an orthographic projection of the packaging component on the first transparent substrate does not overlap with an orthographic projection of the photosensitive area of the sensor chip on the first transparent substrate; and a dimming component for adjusting a light intensity incident on the photosensitive area of the sensor chip, wherein the dimming component is arranged on a side of the first transparent substrate, and an orthographic projection of the dimming component on the first transparent substrate covers the orthographic projection of the photosensitive area of the sensor chip on the first transparent substrate.

In some embodiments, the dimming component and the packaging component are arranged on a same side of the first transparent substrate, and the dimming component comprises a first transparent conductive layer arranged on a surface of the first transparent substrate facing the photosensitive area of the sensor chip.

In some embodiments, the packaging component comprises: a cavity arranged on the side of the first transparent substrate facing the photosensitive area of the sensor chip; a redistribution layer arranged on a surface of the cavity facing away from the first transparent substrate; a barrier solder mask, wherein at least a part of the barrier solder mask is arranged on the surface of the cavity facing away from the first transparent substrate, an orthographic projection of the barrier solder mask on the first transparent substrate surrounds the orthographic projection of the photosensitive area on the first transparent substrate, and a thickness of the part of the barrier solder mask arranged on the surface of the cavity facing away from the first transparent substrate is greater than a thickness of the redistribution layer in a direction perpendicular to the first transparent substrate; and a solder mask face arranged on the side of the first transparent substrate facing the photosensitive area of the sensor chip and covering at least a part of the redistribution layer, wherein the solder mask face comprises a plurality of first through holes.

In some embodiments, the dimming component further comprises a second transparent conductive layer insulated from the first transparent conductive layer, the second transparent conductive layer is arranged on a side of the first conductive layer facing away from the first transparent substrate, the cavity comprises a first cavity part and a second cavity part, and the first cavity part is arranged on a surface of the first transparent conductive layer facing away from the first transparent substrate, the second cavity part is arranged on a surface of the second transparent conductive layer facing away from the first transparent substrate, a surface of the first cavity part facing away from the first transparent substrate is flush with a surface of the second cavity part facing away from the first transparent substrate, the second cavity part comprises at least one second through hole, the redistribution layer is arranged on the surfaces of the first cavity part and the second cavity part facing away from the first transparent substrate, and an orthographic projection of the at least one second through hole on the first transparent substrate is within an orthographic projection of the redistribution layer on the first transparent substrate.

In some embodiments, the packaging component further comprises an electrical connection part arranged in the second through hole and electrically connecting the second transparent conductive layer and the redistribution layer.

In some embodiments, a material of the electrical connection part is the same as a material of the redistribution layer.

In some embodiments, the solder mask face comprises a first mask part and a second mask part, wherein the first mask part is arranged on the surface of the first transparent conductive layer facing away from the first transparent substrate, and the second mask part is arranged on a surface of the cavity or the redistribution layer facing away from the first transparent substrate, a surface of the first mask part facing away from the first transparent substrate is flush with a surface of the second mask part facing away from the first transparent substrate, and the first mask part comprises at least one third through hole, and an orthographic projection of the at least one third through hole on the first transparent substrate is within an orthographic projection of the first transparent conductive layer on the first transparent substrate.

In some embodiments, the dimming component is arranged on a side of the first transparent substrate facing away from the packaging component.

In some embodiments, the dimming component comprises a first transparent conductive layer arranged on a surface of the first transparent substrate facing away from the photosensitive area of the sensor chip.

In some embodiments, the dimming component further comprises a second transparent substrate, and the second transparent substrate and the first transparent substrate are bonded and fixed by an optical transparent adhesive, and the first transparent conductive layer is arranged on a surface of the second transparent substrate facing away from the first transparent substrate.

In some embodiments, the dimming component further comprises: an electrochromic layer arranged on a surface of the first transparent conductive layer facing away from the first transparent substrate; an ion conductive layer arranged on a surface of the electrochromic layer facing away from the first transparent substrate; an ion storage layer arranged on a surface of the ion conductive layer facing away from the first transparent substrate; and a second transparent conductive layer arranged on a surface of the ion storage layer facing away from the first transparent substrate, wherein orthographic projections of the electrochromic layer, the ion conductive layer, the ion storage layer and the second transparent conductive layer on the first transparent substrate are within an orthographic projection of the first transparent conductive layer on the first transparent substrate.

In some embodiments, the dimming component comprises a liquid crystal layer sandwiched between a third transparent substrate and a fourth transparent substrate.

In some embodiments, the dimming component further comprises: a third transparent conductive layer arranged on a surface of the third transparent substrate facing the liquid crystal layer; a first alignment layer arranged on a surface of the third transparent conductive layer facing the liquid crystal layer; a first polarizer arranged on a surface of the third transparent substrate facing away from the liquid crystal layer; a fourth transparent conductive layer arranged on a surface of the fourth transparent substrate facing the liquid crystal layer; a second alignment layer arranged on the surface of the fourth transparent conductive layer facing the liquid crystal layer; and a second polarizer arranged on a surface of the fourth transparent substrate facing away from the liquid crystal layer, wherein a surface of the first polarizer facing away from the third transparent substrate and a surface of the first transparent substrate facing away from the packaging component are bonded and fixed by an optical transparent adhesive.

In some embodiments, the third transparent substrate and the fourth transparent substrate are thin glass substrates.

In some embodiments, the third transparent substrate and the fourth transparent substrate are flexible substrates.

In some embodiments, the dimming component further comprises: a first nano-grating array arranged on a surface of the third transparent substrate facing the liquid crystal layer, the first nano-grating array comprising a plurality of nanowires extending in a first direction; and a second nano-grating array arranged on a surface of the fourth transparent substrate facing the liquid crystal layer, the second nano-grating array comprising a plurality of nanowires extending in a second direction, wherein the first direction is perpendicular to the second direction.

In some embodiments, the dimming component further comprises: a fifth transparent conductive layer arranged a surface of the third transparent substrate facing the liquid crystal layer and filling gaps between a plurality of nanowires of the first nano-grating array; a third alignment layer arranged on a surface of the fifth transparent conductive layer facing the liquid crystal layer; a sixth transparent conductive layer arranged on a surface of the fourth transparent substrate facing the liquid crystal layer and filling gaps between a plurality of nanowires of the second nano-grating array; and a fourth alignment layer arranged on a surface of the sixth transparent conductive layer facing the liquid crystal layer.

In some embodiments, the third transparent substrate and the first transparent substrate are bonded and fixed by an optical transparent adhesive.

In some embodiments, the third transparent substrate and the first transparent substrate are the same transparent substrate.

In some embodiments, the liquid crystal layer adopts twisted nematic liquid crystal.

In some embodiments, the image sensor is a CMOS image sensor.

According to a second aspect of the present disclosure, there is provided a camera compact module, comprising the above image sensor and a lens module on a light incident side of the image sensor.

According to a third aspect of the present disclosure, there is provided an electronic device comprising the above camera compact module.

According to a fourth aspect of the present disclosure, there is provided a method for manufacturing a packaging structure of the above image sensor. The method comprises: providing a first transparent substrate; fabricating a dimming component on a side of the first transparent substrate, wherein an orthographic projection of the dimming component on the first transparent substrate covers an orthographic projection of a photosensitive area of a sensor chip of the image sensor on the first transparent substrate; and fabricating a packaging component on a side of the first transparent substrate, wherein an orthographic projection of the packaging component on the first transparent substrate does not overlap with the orthographic projection of the photosensitive area of the sensor chip of the image sensor on the first transparent substrate.

### BRIEF DESCRIPTION OF THE DRAWINGS

In order to more clearly illustrate the technical solutions in embodiments of the disclosure or in the prior art, the appended drawings needed to be used in the description of the embodiments or the prior art will be introduced briefly in the following. Obviously, the drawings in the following description are only some embodiments of the disclosure, and for those of ordinary skills in the art, other drawings may be obtained according to these drawings under the premise of not paying out creative work.

FIG. 1 shows an exploded view of a camera compact module in the related art;

FIG. 2 shows aperture diagrams in different states;

FIG. 3 shows a schematic diagram of the imaging optical path of the camera compact module;

FIG. 4 shows a sectional view of the basic structure of a conventional image sensor;

FIG. 5 shows a top view of a packaging structure of a conventional image sensor;

FIG. 6 shows a sectional view of the packaging structure of the conventional image sensor taken along line AA in FIG. 5;

FIG. 7 shows a top view of a packaging structure of an image sensor according to an embodiment of the present disclosure;

FIG. 8 shows a sectional view of an image sensor according to an embodiment of the present disclosure, in which the sectional view of a packaging structure is taken along line BB in FIG. 7;

FIG. 9 shows a sectional view of a packaging structure of an image sensor according to an embodiment of the present disclosure;

FIG. 10 shows a sectional view of a packaging structure of an image sensor according to an embodiment of the present disclosure;

FIG. 11 shows a transmittance spectrum of the packaging structure shown in FIG. 8 in the visible light range;

FIG. 12 shows a transmittance spectrum of the packaging structure shown in FIG. 8 in the visible light range;

FIG. 13 shows a sectional view of a packaging structure of an image sensor according to an embodiment of the present disclosure;

FIG. 14 shows a sectional view of a packaging structure of an image sensor according to an embodiment of the present disclosure;

FIG. 15 shows a sectional view of a packaging structure of an image sensor according to an embodiment of the present disclosure.

The shape and thickness of each film layer in the drawings do not reflect the real scale of each film layer, but to schematically illustrate the content of the disclosure.

### DETAILED DESCRIPTION OF THE DISCLOSURE

With the popularity of cameras, there are more and more application scenarios, such as mobile phone photography, drone photography, security monitoring and so on. In various application scenarios, camera can take pictures quickly, but at the same time, some application inconveniences still exist. For example, it is not easy to image in excessively bright light, backlighting shooting leads to black face, and frontlighting shooting leads to overexposure and excessive brightness. Although some problems can be solved by adjusting the aperture size and focal length, it also brings new disadvantages, such as high cost, long focusing time and inapplicability in high-speed imaging field.

Camera compact module is an important component for image capture and the most important part of the camera. FIG. 1 shows an exploded view of a camera compact module in the related art. As shown in FIG. 1, the camera compact module mainly includes a cover 40, a lens module 20, a voice coil motor (VCM) 30, a bracket 50, an infrared filter 60, an image sensor 10, and a printed circuit board (PCB) 70.

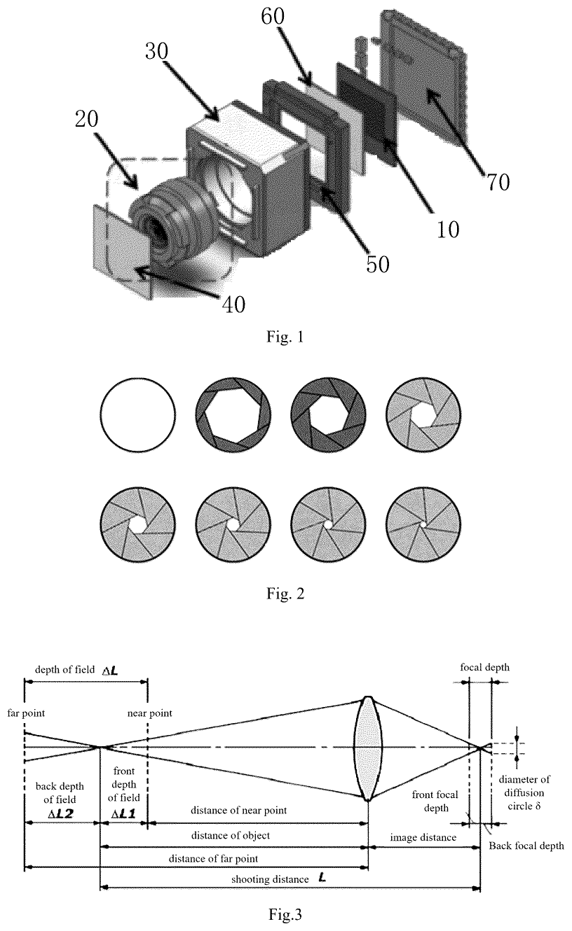

The most important components of the lens module 20 are a lens group and a filter (aperture). Aperture is a device configured to control the amount of light that passes through the lens and enters the photosensitive surface of the image sensor. The aperture is usually arranged in the lens module. The amount of light entering is directly proportional to the square of the effective aperture diameter D of the lens and inversely proportional to the focal length f of the lens, and the ratio of D to f is called relative aperture. The reciprocal of the relative aperture is called the aperture number, also called the F number, and F=f/D. The smaller the aperture number is, the larger the aperture diameter is, and the more light enters in the same unit time. FIG. 2 shows the aperture diagrams in different states.

The function of the voice coil motor 30 is to drive the elastic sheet/spring to move by controlling the current, and adjust the position of each lens in the lens module in three axes (XYZ), so that the focused object presents the clearest state. In short, the voice coil motor adjusts the focal length.

The image sensor 10 is the core component of the camera compact module, which converts an optical signal into an electrical signal and converts it into a digital signal through a readout circuit. CMOS image sensor (CIS) is a kind of image sensor commonly used in camera compact module. FIG. 3 shows a schematic diagram of the imaging optical path of the camera compact module. As shown in FIG. 3, the imaging optical path is as follows: light enters from the lens module; the amount of light entering is adjusted by the aperture; the focal length is adjusted by the lens group; after passing through the packaging substrate of the image sensor, light is incident on the sensor chip, which is located in the focal plane of the optical path.

The correlation can be expressed by the following formula:

$$Δ L = \frac{2 {f}^{2} F δ {L}^{2}}{{f}^{4} - {F}^{2} {δ}^{2} {L}^{2}}$$

wherein ΔL represents the depth of field, f represents the focal length (image distance), F represents the aperture number, L represents the shooting distance, and δ represents the diameter of the diffusion circle. In the camera compact module, the diameter of the diffusion circle is generally a fixed value, so it is necessary to adjust the aperture number and focal length to appropriate values in order to image clearly.

What is described above is a camera compact module which includes an aperture and can adjust the focal length. In addition, some low-cost camera compact modules, which use fixed focus or no aperture scheme, can't image at all when dealing with changing light scenes.

In the related art, in order to clearly image, a single dimming component is usually arranged in the camera compact module (for example, arranged at the light entrance side of the lens group, the light exit side of the lens group or between adjacent lenses in the lens group). This structure will obviously increase the overall thickness of the camera compact module, which is not conducive to the thinning of the device. The disclosure provides a packaging structure of an image sensor, which integrates a dimming component into the packaging structure of the image sensor, thereby greatly reducing the thickness of a camera compact module. Under the condition of not increasing cost, the image sensor in the present disclosure can effectively adjust the brightness of incident light, so that it can quickly image in a high brightness range. Since there is no need to change the aperture size, there is no need to readjust the focal length, thereby the imaging time is greatly shortened.

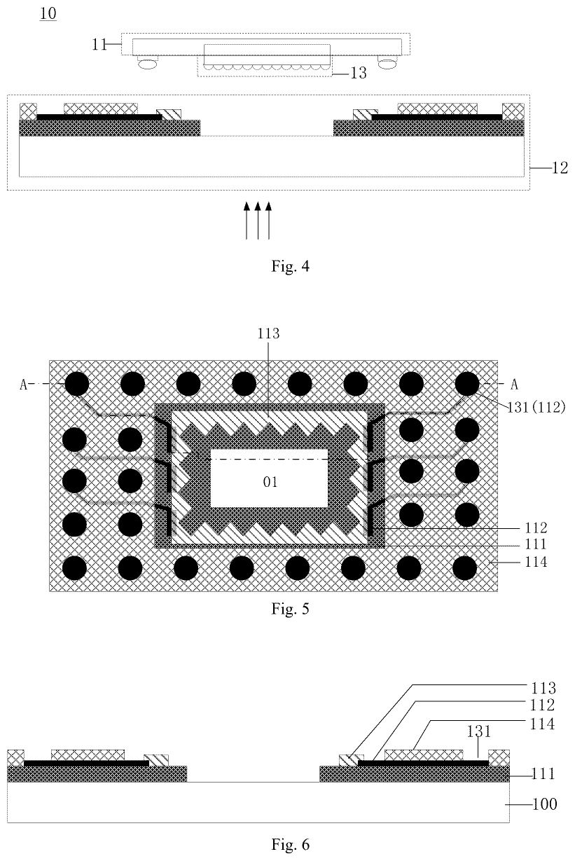

FIG. 4 shows a sectional view of the basic structure of a conventional image sensor. The image sensor 10 generally includes a sensor chip 11, an optical film layer 13 on a light incident side of the sensor chip 11, and a packaging structure 12. The optical film layer 13 generally includes a color filter film and a microlens structure. The incident direction of light is indicated by the arrow in FIG. 4. FIG. 5 shows a top view of a packaging structure of a conventional image sensor. FIG. 6 shows a sectional view of the packaging structure of the conventional image sensor taken along line AA in FIG. 5. As shown in FIG. 5 and FIG. 6, the packaging structure 12 of the conventional image sensor includes a first transparent substrate 100, a cavity 111, a redistribution layer 112, a barrier solder mask 113 and a solder mask face 114. The cavity 111 is configured to accommodate optical film layers, and the redistribution layer 112 is usually a conductive layer with Cu as the main material. The barrier solder mask 113 is configured to form a wall around the photosensitive area 01 to prevent the adhesive used in the packaging process from entering the photosensitive area 01. The pads of the sensor chip are generally distributed in dots, and there are still some gaps between the sensor chip and the packaging structure after welding the pads of the sensor chip and the packaging structure. In order to enhance the bonding strength between the sensor chip and the packaging structure and avoid particulate pollutants from entering the photosensitive area, an adhesive can be arranged to fill the gaps between the sensor chip and the packaging structure, such as an epoxy adhesive. The solder mask face 114 is configured to protect the redistribution layer and reserve positions (i.e., positions for first through holes 131) where the solder material (e.g., Sn ball) needs to be applied subsequently.

For manufacturing the packaging structure of the conventional image sensor shown in FIG. 5 and FIG. 6, the following steps may be adopted: 1. Manufacturing cavity: the cavity is fabricated by processes such as spin coating and exposure development for subsequently accommodating the optical film layers of the image sensor, the material of the cavity may be resin, and the thickness of the cavity is generally 30 μm; 2. Manufacturing redistribution layer: the redistribution layer is fabricated by processes such as electroplating, exposure development, etching, the material of the redistribution layer is mainly Cu, and the thickness is generally 3-4 μm; 3. Manufacturing barrier solder mask: the barrier solder mask is fabricated by processes such as spin coating, exposure development, to form a wall around the photosensitive area of the image sensor to prevent the adhesive used in the packaging process from entering the photosensitive area, the material of the barrier solder mask may be resin, and the thickness of the barrier solder mask is generally 10 μm; 4. Manufacturing solder mask face: the solder mask face is fabricated by processes such as spin coating, exposure development, to protect the redistribution layer and reserve positions where the solder material needs to be applied subsequently, the material of the solder mask face may be resin, and the thickness of the solder mask face is generally 15 μm, and a diameter of a first through hole may be 100 μm.

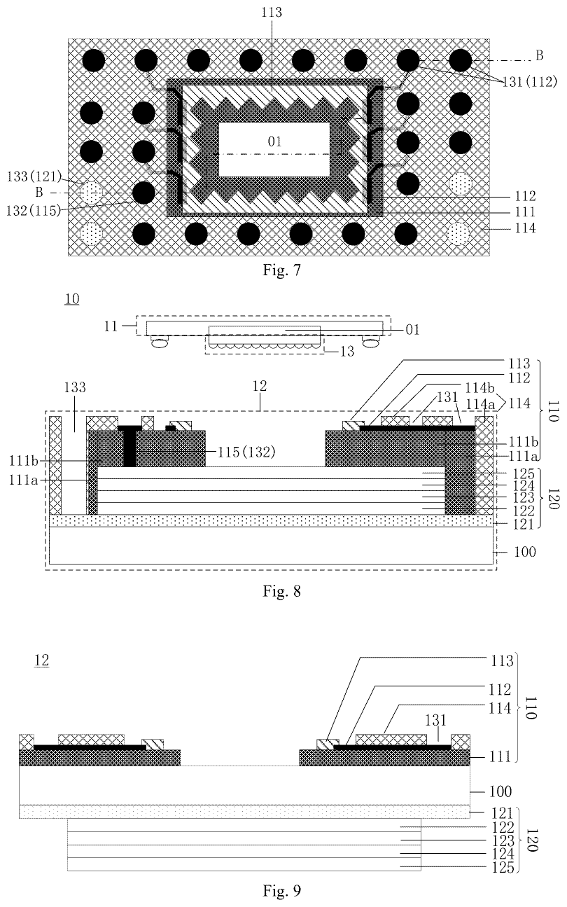

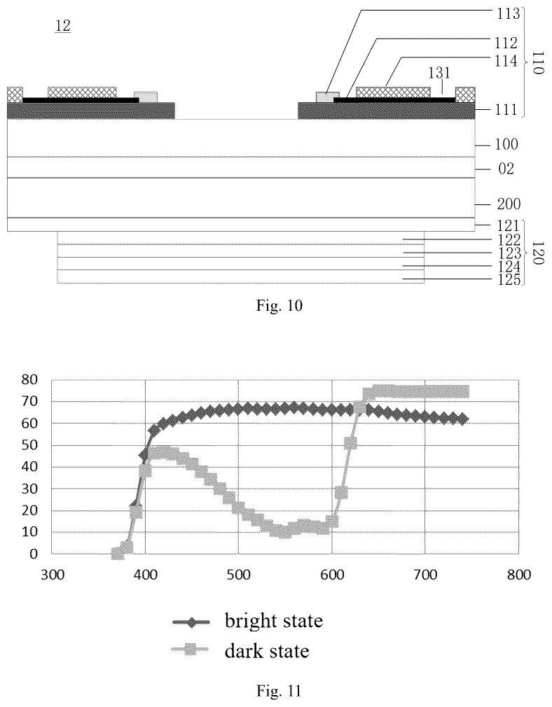

According to a first aspect of the present disclosure, an image sensor is provided. FIG. 7 shows a top view of a packaging structure of an image sensor according to an embodiment of the present disclosure. FIG. 8 shows a sectional view of an image sensor according to an embodiment of the present disclosure, in which the sectional view of a packaging structure is taken along line BB in FIG. 7. FIGS. 9-13 respectively show sectional views of a packaging structure of an image sensor according to an embodiment of the present disclosure. Referring to FIGS. 7-13, the packaging structure 12 of the image sensor 10 provided by an embodiment of the present disclosure may comprises: a first transparent substrate 100; a packaging component 110 for packaging the sensor chip, wherein the packaging component 110 is arranged on a side of the first transparent substrate 100 facing a photosensitive area 01 of the sensor chip 11, and an orthographic projection of the packaging component 110 on the first transparent substrate 100 does not overlap with an orthographic projection of the photosensitive area 01 of the sensor chip on the first transparent substrate 100; and a dimming component 120 for adjusting a light intensity incident on the photosensitive area 01 of the sensor chip, wherein the dimming component 120 is arranged on a side of the first transparent substrate 100, and an orthographic projection of the dimming component 120 on the first transparent substrate 100 covers the orthographic projection of the photosensitive area 01 of the sensor chip 11 on the first transparent substrate 100.

Referring to FIGS. 7-13, the packaging component 110 may comprise a cavity 111 arranged on a side of the first transparent substrate 100 facing the photosensitive area of the sensor chip; a redistribution layer 112 arranged on a surface of the cavity 111 facing away from the first transparent substrate 100; a barrier solder mask 113, at least a part of the barrier solder mask is arranged on the surface of the cavity 111 facing away from the first transparent substrate 100, and an orthographic projection of the barrier solder mask 113 on the first transparent substrate 100 surrounds the orthographic projection of the photosensitive area 01 on the first transparent substrate 100, and a thickness of the part of the barrier solder mask 113 arranged on the surface of the cavity 111 facing away from the first transparent substrate 100 is greater than a thickness of the redistribution layer 112 in a direction perpendicular to the first transparent substrate 100; and a solder mask face 114 arranged on the side of the first transparent substrate 100 facing the photosensitive area of the sensor chip and covering at least a part of the redistribution layer 112, wherein the solder mask face 114 comprises a plurality of first through holes 131. The plurality of first through holes on the solder mask face expose the redistribution layer, and Sn ball solder may be applied to the first through holes subsequently to fan out the circuit of the sensor chip to the PCB.

In some embodiments, as shown in FIGS. 7-13, a part of the barrier solder mask 113 may be arranged on the surface of the cavity 111 facing away from the first transparent substrate 100, and the other part of the barrier solder mask 113 may be arranged on the surface of the redistribution layer 112 facing away from the first transparent substrate 100. In other embodiments, the barrier solder mask may be completely arranged on the surface of the cavity facing away from the first transparent substrate, as long as the thickness of the barrier solder mask is greater than the thickness of the redistribution layer. Since the thickness of the barrier solder mask is greater than the thickness of the redistribution layer, the barrier solder mask can effectively prevent the adhesive used in the subsequent packaging process from entering the photosensitive area.

In some embodiments, the dimming component may be an electrochromic functional layer. As shown in FIGS. 8-10, the dimming component 120 may comprise: a first transparent conductive layer 121 arranged on a side of the first transparent substrate 100; an electrochromic layer 122 arranged on a surface of the first transparent conductive layer 121 facing away from the first transparent substrate 100; an ions conductor layer 123 arranged on a surface of the electrochromic layer 122 facing away from the first transparent substrate 100; an ions storage layer 124 arranged on a surface of the ion conductive layer 123 facing away from the first transparent substrate 100; a second transparent conductive layer 125 arranged on a surface of the ion storage layer 124 facing away from the first transparent substrate 100. The orthographic projections of the electrochromic layer 122, the ion conductive layer 123, the ion storage layer 124 and the second transparent conductive layer 125 on the first transparent substrate 100 is within the orthographic projection of the first transparent conductive layer 121 on the first transparent substrate 100.

According to the embodiments of the present disclosure, the light transmittance is adjusted by using the electrochromic dimming component 120 without adjusting the F value of the aperture, so that clear imaging can be realized without adjusting the focal length through the voice coil motor. For a high-level camera with an aperture and a zoom, in the application scene where the incident light intensity changes rapidly, such as a drone flying against light, the aperture and focal length of the camera do not need to be changed, and the transmittance can be quickly adjusted through the electrochromic functional layer to realize fast and clear imaging. For a low-cost aperture-free camera, normal imaging cannot be performed in an environment that is too bright or too dark. According to the disclosure, the light transmittance is adjusted through the electrochromic functional layer, thus the imaging in the brightest place and the darkest place can better balanced for the aperture-free camera, and a wider dynamic range is obtained.

In some embodiments, as shown in FIG. 8, the dimming component (electrochromic functional layer) 120 and the packaging component 110 are arranged on a same side of the first transparent substrate 100. The first transparent conductive layer 121 is arranged on the surface of the first transparent substrate 100 facing the photosensitive area of the sensor chip, the electrochromic layer 122 is arranged on a surface of the first transparent conductive layer 121 facing away from the first transparent substrate 100, the ionic conductive layer 123 is arranged on a surface of the electrochromic layer 122 facing away from the first transparent substrate 100, the ion storage layer 124 is arranged on a surface of the ion conductive layer 123 facing away from the first transparent substrate 100, and the second transparent conductive layer 125 is arranged on a surface of the ion storage layer 124 facing away from the first transparent substrate 100.

The electrochromic functional layer and the packaging component are directly integrated on the same transparent substrate, and no additional substrate is needed, so that the overall thickness of the image sensor is reduced by at least 200 μm.

In some embodiments, as shown in FIG. 8, the cavity 111 comprises a first cavity part 111a and a second cavity part 111b, wherein the first cavity part 111a is arranged on the surface of the first transparent conductive layer 121 facing away from the first transparent substrate 100, and the second cavity part 111b is arranged on the surface of the second transparent conductive layer 125 facing away from the first transparent substrate 100. A surface of the first cavity part 111a facing away from the first transparent substrate 100 is flush with a surface of the second cavity part 111b facing away from the first transparent substrate 100. The second cavity part 111b comprises at least one second through hole 132, and the redistribution layer 112 is arranged on the surfaces of the first cavity part 111a and the second cavity part 111b facing away from the first transparent substrate 100. An orthographic projection of the at least one second through hole 132 on the first transparent substrate 100 is within the orthographic projection of the redistribution layer 112 on the first transparent substrate 100.

In some embodiments, as shown in FIG. 8, the packaging component 110 further comprises an electrical connection part 115, which is arranged in the second through hole 132 and electrically connects the second transparent conductive layer 125 and the redistribution layer 112. The second transparent conductive layer of the electrochromic functional layer and the redistribution layer of the packaging component are connected through the electrical connection part, so that the lead wire for applying an electrical signal to the electrochromic functional layer may share a same film layer with the redistribution layer, thereby simplifying circuit wiring and achieving a simple process, a high yield and a low cost for the whole packaging structure.

In some embodiments, the material of the electrical connection part may be the same as the material of the redistribution layer. The electrical connection part and the redistribution layer can be formed together by the same process, which simplifies the preparation process.

In some embodiments, as shown in FIG. 8, the solder mask face 114 comprises a first mask part 114a arranged on the surface of the first transparent conductive layer 121 facing away from the first transparent substrate 100 and a second mask part 114b arranged on the surface of the cavity 111 or the redistribution layer 112 facing away from the first transparent substrate 100. A surface of the first mask part 114a facing away from the first transparent substrate 100 is flush with a surface of the second mask part 114b facing away from the first transparent substrate 100. The first mask part 114a comprises at least one third through hole 133, and an orthographic projection of the at least one third through hole 133 on the first transparent substrate 100 is within the orthographic projection of the first transparent conductive layer 121 on the first transparent substrate 100. The third through holes 133 exposes a part of the first transparent conductive layer 121, and a conductive material can be arranged in the third through holes, thereby applying an electrical signal to the first transparent conductive layer.

For manufacturing the packaging structure shown in FIG. 8, the following steps may be adopted: 1. Manufacturing first transparent conductive layer: the first transparent conductive layer is fabricated on a surface of the first transparent substrate by processes such as magnetron sputtering, slit coating. The material of the first transparent conductive layer may be inorganic materials such as ITO, IZO, FTO, and the thickness of the first transparent conductive layer may be 40-100 nm, for example, 52 nm. 2. Manufacturing electrochromic layer: An inorganic electrochromic layer may be fabricated on the first transparent conductive layer by processes such as magnetron sputtering, electrochemical deposition, vapor deposition. The material of the inorganic electrochromic layer may be NiO, V₂O₅, WO₃, MoO₃, etc., and the thickness of the inorganic electrochromic layer may be 100-1200 nm, for example, 200-800 nm; alternatively, an organic electrochromic layer may be fabricated on the first transparent conductive layer by processes such as slit coating, concave coating and spin coating, the material of the organic electrochromic layer may be PEDOT (poly (3,4-ethylenedioxythiophene), polyaniline and various modified derivatives thereof, and the thickness of the organic film layer may generally be 200-400 nm, for example, 300 nm; 3. Manufacturing ion conductive layer: the ion conductive layer is fabricated on the electrochromic layer by magnetron sputtering process, the material of ion conductive layer may be LiTaO₃, LiPON, Ta₂O₅, LiNbO₃, etc., and the thickness of the ion conductive layer is generally 50-800 nm. 4. Manufacturing ion storage layer: the ion storage layer is fabricated on the ion conductive layer by magnetron sputtering process, the material of the ion storage layer may be TiO₂, V₂O₅, NiO₅, and the thickness of the ion storage layer is generally 100-800 nm, for example, 150-500 nm. 5. Manufacturing second transparent conductive layer: the second transparent conductive layer is fabricated on the ion storage layer by processes such as magnetron sputtering and slit coating, the material of the second transparent conductive layer may be inorganic materials such as ITO, IZO and FTO, and the thickness of the second transparent conductive layer may be 40-100 nm, for example, 52 nm; 6. Manufacturing cavity: the cavity is fabricated by processes such as spin coating and exposure development for subsequently accommodating the optical film layers of the image sensor, the material of the cavity may be resin, and the thickness of the cavity is generally 30 μm; 7. Manufacturing redistribution layer: the redistribution layer is fabricated by processes such as electroplating, exposure development, etching, the material of the redistribution layer is mainly Cu, and the thickness is generally 3-4 μm; 8. Manufacturing barrier solder mask: the barrier solder mask is fabricated by processes such as spin coating, exposure development, to form a wall around the photosensitive area of the image sensor to prevent the adhesive used in the packaging process from entering the photosensitive area, the material of the barrier solder mask may be resin, and the thickness of the barrier solder mask is generally 10 μm; 9. Manufacturing solder mask face: the solder mask face is fabricated by processes such as spin coating, exposure development, to protect the redistribution layer and reserve positions where the solder material needs to be applied subsequently, the material of the solder mask face may be resin, and the thickness of the solder mask face is generally 15 μm, and a diameter of a first through hole may be 100 μm.

In some embodiments, as shown in FIGS. 9 and 10, a dimming component (electrochromic functional layer) 120 is arranged on a side of the first transparent substrate 100 facing away from the packaging component 110.

In some embodiments, as shown in FIG. 9, the first transparent conductive layer 121 is arranged on the surface of the first transparent substrate 100 facing away from the photosensitive area of the sensor chip, the electrochromic layer 122 is arranged on the surface of the first transparent conductive layer 121 facing away from the first transparent substrate 100, the ion conductive layer 123 is arranged on the surface of the electrochromic layer 122 facing away from the first transparent substrate 100, and the ion storage layer 124 is arranged on the ion conductive layer 123 facing away from the first transparent substrate 100.

For the packaging structure shown in FIG. 9, the dimming component (electrochromic functional layer) may be fabricated on the first transparent substrate first, and then the first transparent substrate is turned over to fabricate the packaging component, and the specific fabrication processes of the electrochromic functional layer and the packaging component will not describe in detail herein. The electrochromic functional layer and the packaging component are directly integrated on the same transparent substrate, and no additional substrate is needed, thus effectively reducing the thickness of the packaging structure. Meanwhile, since the first transparent conductive layer and the second transparent conductive layer of the electrochromic functional layer are not covered by the film layer of the packaging component, there is no need to arrange a through hole to expose the first transparent conductive layer and the second transparent conductive layer, and the electrochromic functional layer can be directly controlled, thus reducing the preparation process.

In some embodiments, as shown in FIG. 10, the dimming component (electrochromic functional layer) 120 may further comprise a second transparent substrate 200, and the second transparent substrate 200 and the first transparent substrate 100 are bonded and fixed by an optical transparent adhesive 02. As shown in FIG. 10, the first transparent conductive layer 121 is arranged on a surface of the second transparent substrate 200 facing away from the first transparent substrate 100, the electrochromic layer 122 is arranged on a surface of the first transparent conductive layer 121 facing away from the second transparent substrate 200, the ionic conductive layer 123 is arranged on a surface of the electrochromic layer 122 facing away from the second transparent substrate 200, the ion storage layer 124 is arranged on a surface of the ionic conductive layer 123 facing away from the second transparent substrate 200, and the second transparent conductive layer 125 is arranged on a surface of the ion storage layer 124 facing away from the second transparent substrate 200.

For the packaging structure shown in FIG. 10, a packaging component and a dimming component (electrochromic functional layer) can be respectively fabricated on the first transparent substrate and the second transparent substrate, and then the first transparent substrate and the second transparent substrate can be bonded together. The specific bonding process can adopt the following steps: forming a layer of optical transparent adhesive on the back of any transparent substrate by processes such as slit coating, spin coating, spray coating, micro-concave coating, then bonding another transparent substrate with the optical transparent adhesive, and then curing by anneal or ultraviolet radiation. Since the packaging component and the dimming component are manufactured separately, the manufacturing processes of the two components do not affect each other. Meanwhile, since the first transparent conductive layer and the second transparent conductive layer of the electrochromic functional layer are not covered by the film layer of the packaging component, there is no need to arrange a through hole to expose the first transparent conductive layer and the second transparent conductive layer, and the electrochromic functional layer can be directly controlled, thus reducing the preparation process.

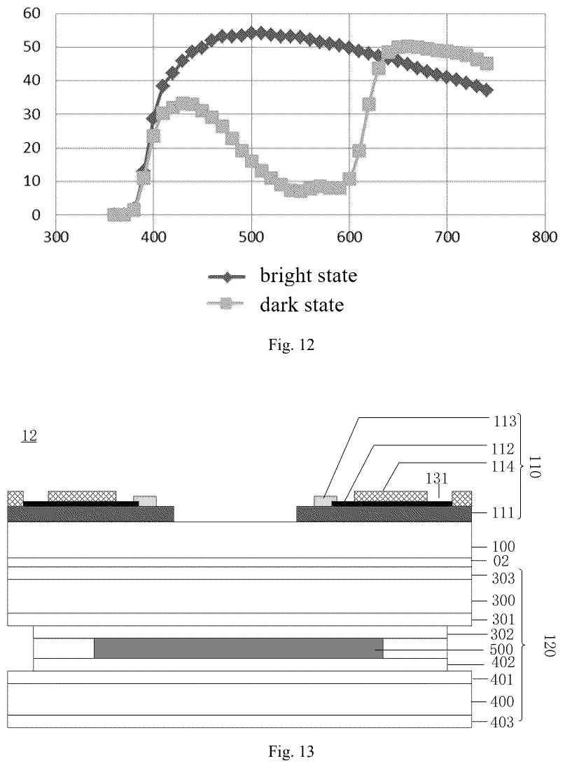

FIGS. 11 and 12 are transmittance spectra of the packaging structure shown in FIG. 8 in the visible light range. For a driving voltage in the range of −0.6v-1v, the transmittance of the sample in FIG. 11 can be adjusted in the range of 20-66%, and the transmittance of the sample in FIG. 12 can be adjusted in the range of 14-52%.

In some embodiments, as shown in FIGS. 13-15, the dimming component 120 may comprise a liquid crystal layer 500 sandwiched between a third transparent substrate 300 and a fourth transparent substrate 400.

In some embodiments, as shown in FIG. 13, the dimming component 120 further comprises: a third transparent conductive layer 301 arranged on a surface of the third transparent substrate 300 facing the liquid crystal layer 500; a first alignment layer 302 arranged on a surface of the third transparent conductive layer 301 facing the liquid crystal layer 500; a first polarizer 303 arranged on a surface of the third transparent substrate 300 facing away from the liquid crystal layer 500; a fourth transparent conductive layer 401 arranged on a surface of the fourth transparent substrate 400 facing the liquid crystal layer 500; a second alignment layer 402 arranged on a surface of the fourth transparent conductive layer 401 facing the liquid crystal layer 500; and a second polarizer 403 arranged on a surface of the fourth transparent substrate 400 facing away from the liquid crystal layer 500. A surface of the first polarizer 303 facing away from the third transparent substrate 300 and a surface of the first transparent substrate 100 facing away from the packaging component 110 are bonded and fixed by an optical transparent adhesive 02.

For manufacturing the packaging structure shown in FIG. 13, the following steps may be adopted: 1. fabricating a third transparent conductive layer and a fourth transparent conductive layer on a surface of the third transparent substrate and a surface of the fourth transparent substrate, respectively. The material of the transparent conductive layer may be ITO, and the thickness of the transparent conductive layer may be 10-100 nm, for example, 52 nm; 2. fabricating a first alignment layer and a second alignment layer on the surface of the third transparent conductive layer and the surface of the fourth transparent conductive layer, respectively, and aligning the first alignment layer and the second alignment layer. The thickness of the first alignment layer and the second alignment layer may be 10-200 nm, for example, 80 nm; 3. fabricating a liquid crystal cell. The thickness of the liquid crystal cell is generally 3 μm, and the thickness range may be adjusted according to the liquid crystal characteristics, ranging from 1 to 25 μm; 4. attaching a first polarizer and a second polarizer on the surface of the third transparent substrate and the surface of the fourth transparent substrate facing away from the liquid crystal layer, respectively. The thickness of a polarizer ranges from 50 to 200 μm, such as 70 to 80 μm; 5. fabricating the packaging component, and the specific fabricating steps will not detailed in detail herein; 6. bonding the dimming component and the packaging component. A layer of optical transparent adhesive on the back of the first transparent substrate or the third transparent substrate is formed by process such as slit coating, rotary coating, spraying, micro-concave coating, then bonding the other transparent substrate with the optical transparent adhesive, and then curing by anneal or ultraviolet radiation.

Using liquid crystal layer as dimming function layer can realize real-time adjustment of transmittance, and the adjustment range of transmittance is wider.

In some embodiments, the third transparent substrate and the fourth transparent substrate are thin glass substrates, and the thickness of thin glass may be 0.1 mm-1.1 mm. Preferably, thin glass with a thickness of 0.25 mm may be selected.

In some embodiments, the third transparent substrate and the fourth transparent substrate are flexible substrates, and the materials of the flexible substrates may be, for example, PET, CPI, PA. The thickness of the flexible substrate may be smaller than the thickness of the glass substrate, thereby further reducing the overall thickness of the device.

In some embodiments, rigid polarizers may be used for the first polarizer and the second polarizer, so that the third transparent substrate and the fourth transparent substrate can be omitted, thereby further reducing the overall thickness of the device.

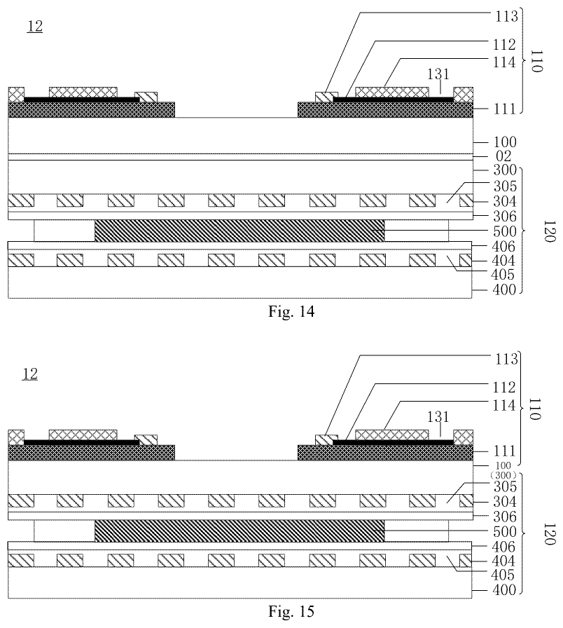

In some embodiments, as shown in FIG. 14, the dimming component further comprises a first nano-grating array 304 arranged on a surface of the third transparent substrate 300 facing the liquid crystal layer 500, the first nano-grating array comprising a plurality of nanowires extending in a first direction; and a second nano-grating array 404 arranged on a surface of the fourth transparent substrate 400 facing the liquid crystal layer 500, the second nano-grating array 404 comprising a plurality of nanowires extending in a second direction, wherein the first direction is perpendicular to the second direction. In the embodiment, the first nano-grating array and the second nano-grating array play the role of polarization, and the principle is as follows: TE waves parallel to the direction of the metal wire grid drive electrons in the metal wire to oscillate along the length direction of the metal wire, and the electrons collide with atoms in the metal lattice, so that the TE waves are attenuated and accompanied by radiation; the electron movement in the metal wire driven by TM wave perpendicular to the wire grid direction is limited, which weakens the attenuation and radiation, so that TM wave can pass through the metal wire with little change. Two grid polarizers are made orthogonally, and the sandwiched liquid crystal layer uses twisted nematic liquid crystal, and the pitch is set so that the two substrates rotate by 90 degrees. The light is polarized by the first nano-grating array, then rotated by the liquid crystal layer, and then emitted by the second nano-grating array. Thus, the light transmittance can be adjusted by adjusting the deflection angle of the liquid crystal layer.

In some embodiments, as shown in FIG. 14, the dimming component may further comprise: a fifth transparent conductive layer 305 arranged on a surface of the third transparent substrate 300 facing the liquid crystal layer 500 and filling gaps between a plurality of nanowires of the first nano-grating array 304; a third alignment layer 306 arranged on a surface of the fifth transparent conductive layer 305 facing the liquid crystal layer 500, a sixth transparent conductive layer 405 arranged on a surface of the fourth transparent substrate 400 facing the liquid crystal layer 500 and filling gaps between a plurality of nanowires of the second nano-grating array 404; a fourth alignment layer 406 arranged on a surface of the sixth transparent conductive layer 405 facing the liquid crystal layer 500.

In the embodiment shown in FIG. 14, the third transparent substrate 300 and the first transparent substrate 100 are bonded and fixed by an optical transparent adhesive.

For the packaging structure shown in FIG. 14, the following steps may be adopted: 1. fabricating the first nano-grating array and the second nano-grating array on the third transparent substrate and the fourth transparent substrate, respectively; coating a nano-imprint layer of materials such as polymeric organosilicon compounds with processes such as spin coating, slit coating, and then imprinting nano-gratings on the surface of the materials with nano-imprint soft molds. The grating size is as followings: wire width is 10 nm-1000 nm, wire grid pitch is 20-2000 nm, and wire grid height is 10-1000 nm. The specific parameters can be specifically adjusted according to the minimum wavelength and maximum wavelength of polarization and the required transmittance; 2. fabricating transparent conductive layers and alignment layers respectively on the third substrate and the fourth substrate, and aligning the alignment layers; 3. fabricating the liquid crystal cell; 4. fabricating the packaging component on the first transparent substrate, the specific steps are the same as above, which will not be repeated herein; 5. bonding the dimming component and the packaging component.

In some embodiments, as shown in FIG. 15, the third transparent substrate and the first transparent substrate are the same transparent substrate, that is, the dimming component and the packaging component share the same substrate, which can reduce the thickness of one substrate and further reduce the overall thickness of the device.

For the packaging structure shown in FIG. 15, the following steps may be adopted: 1. fabricating the packaging component on the first transparent substrate, and the specific steps are the same as above, which will not be repeated herein; 2. fabricating a nano-imprint layer on the surface of the first transparent substrate facing away from the packaging component to form the first nano-grating array, fabricating the fifth transparent conductive layer and the third alignment layer, and aligning the third alignment layer; 3. fabricating a nano-imprint layer on the fourth transparent substrate to form the second nano-grating array, fabricating the sixth transparent conductive layer and the fourth alignment layer, and aligning the fourth alignment layer; 4. Fabricating the liquid crystal cell.

In the embodiments where the liquid crystal layer is used for dimming, the liquid crystal layer can adopt twisted nematic liquid crystal.

In the embodiments of the present disclosure, the image sensor may be a CMOS image sensor.

According to a second aspect of the present disclosure, there is provided a camera compact module, comprising an image sensor provided in any of the foregoing embodiments, and a lens module on a light incident side of the image sensor.

According to a third aspect of the present disclosure, there is provided an electronic device comprising the camera compact module.

According to a fourth aspect of the present disclosure, there is provided a method for manufacturing a packaging structure of an image sensor provided in any of the foregoing embodiments. The method comprises: providing a first transparent substrate; fabricating a dimming component on a side of the first transparent substrate, wherein an orthographic projection of the dimming component on the first transparent substrate covers an orthographic projection of a photosensitive area of a sensor chip of the image sensor on the first transparent substrate; and fabricating a packaging component on a side of the first transparent substrate, wherein an orthographic projection of the packaging component on the first transparent substrate does not overlap with the orthographic projection of the photosensitive area of the sensor chip of the image sensor on the first transparent substrate.

In some embodiments, fabricating a packaging component on a side of the first transparent substrate comprises: fabricating a cavity on a side of the first transparent substrate facing the photosensitive area of the sensor chip; fabricating a redistribution layer on a surface of the cavity facing away from the first transparent substrate; fabricating a barrier solder mask, wherein at least a part of the barrier solder mask is arranged on the surface of the cavity facing away from the first transparent substrate, an orthographic projection of the barrier solder mask on the first transparent substrate surrounds the orthographic projection of the photosensitive area on the first transparent substrate, and a thickness of the part of the barrier solder mask arranged on the surface of the cavity facing away from the first transparent substrate is greater than a thickness of the redistribution layer in a direction perpendicular to the first transparent substrate; fabricating a solder mask face on the side of the first transparent substrate facing the photosensitive area of the sensor chip, wherein the solder mask face covers at least a part of the redistribution layer, and the solder mask face comprises a plurality of first through holes.

In some embodiments, fabricating a dimming component on a side of the first transparent substrate comprises: fabricating a first transparent conductive layer on a side of the first transparent substrate; fabricating an electrochromic layer on a surface of the first transparent conductive layer facing away from the first transparent substrate; fabricating an ion conductive layer on a surface of the electrochromic layer facing away from the first transparent substrate; fabricating an ion storage layer on a surface of the ion conductive layer facing away from the first transparent substrate; fabricating a second transparent conductive layer on a surface of the ion storage layer facing away from the first transparent substrate. The orthographic projections of the electrochromic layer, the ion conductive layer, the ion storage layer and the second transparent conductive layer on the first transparent substrate is within the orthographic projection of the first transparent conductive layer on the first transparent substrate.

In some embodiments, fabricating a dimming component on a side of the first transparent substrate comprises: fabricating a liquid crystal layer on a side of the first transparent substrate, and the liquid crystal layer is sandwiched between a third transparent substrate and a fourth transparent substrate.

In the drawings, the thickness of areas and layers may be exaggerated for clarity. In the drawings, the same reference numerals denote the same or similar structures, and therefore their detailed description is omitted. The described features, structures, or characteristics may be combined in any suitable manner in one or more embodiments. In the description, numerous specific details are provided to give a thorough understanding of the embodiments of the present disclosure. However, those skilled in the art will realize that the technical solution of the present disclosure can be practiced without one or more of the specific details, or other methods, components, materials, etc. can be adopted. In other instance, well-known structures, material or operations are not shown or described in detail to avoid obscuring that main technical concept of the present disclosure.

Spatial relative terms such as “row”, “column”, “up”, “down”, “left” and “right” can be used in the disclosure to describe the relationship between one element or feature and another element or feature as illustrated in the figures. It will be understood that these spatially relative terms are intended to cover different orientations of devices in use or operation other than those depicted in the figures. For example, if the device in the figure is turned over, elements described as “under other elements or features” or “below other elements or features” will be oriented as “above other elements or features” and elements described as “to the left of other elements” will be oriented as “to the right of other elements”. Thus, the exemplary term “under” can cover both orientations of “above” and “under”, and the exemplary term “to the left of” can cover both orientations of “to the left” and “to the right”. Devices can be oriented in other ways (rotated by 90 degrees or in other orientations) and the spatial relative descriptors used herein should be interpreted accordingly. In addition, it will also be understood that when a layer is referred to as “between two layers”, it may be the only layer between the two layers, or there may be one or more intermediate layers.

In the description of this specification, descriptions referring to the terms “one embodiment”, “another embodiment” and the like mean that a specific feature, structure, material or characteristic described in connection with this embodiment is included in at least one embodiment of this disclosure. In this specification, the schematic expressions of the above terms are not necessarily aimed at the same embodiment or example. Moreover, the specific features, structures, materials or characteristics described may be combined in any one or more embodiments or examples in a suitable manner. In addition, those skilled in the art can combine different embodiments or examples and features of different embodiments or examples described in this specification without contradicting each other. In addition, it should be noted that in this specification, the terms “first” and “second” are only used for descriptive purposes, and cannot be understood as indicating or implying relative importance or implicitly indicating the number of indicated technical features.

The above embodiments are only used for explanations rather than limitations to the present disclosure, the ordinary skilled person in the related technical field, in the case of not departing from the spirit and scope of the present disclosure, may also make various modifications and variations, therefore, all the equivalent solutions also belong to the scope of the present disclosure, the patent protection scope of the present disclosure should be defined by the claims.

1. An image sensor, comprising a sensor chip and a packaging structure, wherein the packaging structure comprises:
a first transparent substrate;
a packaging component for packaging the sensor chip, wherein the packaging component is arranged on a side of the first transparent substrate facing a photosensitive area of the sensor chip, and an orthographic projection of the packaging component on the first transparent substrate does not overlap with an orthographic projection of the photosensitive area of the sensor chip on the first transparent substrate; and
a dimming component for adjusting a light intensity incident on the photosensitive area of the sensor chip, wherein the dimming component is arranged on a side of the first transparent substrate, and an orthographic projection of the dimming component on the first transparent substrate covers the orthographic projection of the photosensitive area of the sensor chip on the first transparent substrate.

2. The image sensor according to claim 1, wherein the dimming component and the packaging component are arranged on a same side of the first transparent substrate, and the dimming component comprises a first transparent conductive layer arranged on a surface of the first transparent substrate facing the photosensitive area of the sensor chip.

3. The image sensor according to claim 1, wherein the packaging component comprises:
a cavity arranged on the side of the first transparent substrate facing the photosensitive area of the sensor chip;
a redistribution layer arranged on a surface of the cavity facing away from the first transparent substrate;
a barrier solder mask, wherein at least a part of the barrier solder mask is arranged on the surface of the cavity facing away from the first transparent substrate, an orthographic projection of the barrier solder mask on the first transparent substrate surrounds the orthographic projection of the photosensitive area on the first transparent substrate, and a thickness of the part of the barrier solder mask arranged on the surface of the cavity facing away from the first transparent substrate is greater than a thickness of the redistribution layer in a direction perpendicular to the first transparent substrate; and
a solder mask face arranged on the side of the first transparent substrate facing the photosensitive area of the sensor chip and covering at least a part of the redistribution layer, wherein the solder mask face comprises a plurality of first through holes.

4. The image sensor according to claim 3, wherein the dimming component further comprises a second transparent conductive layer insulated from the first transparent conductive layer, the second transparent conductive layer is arranged on a side of the first conductive layer facing away from the first transparent substrate, the cavity comprises a first cavity part and a second cavity part, and the first cavity part is arranged on a surface of the first transparent conductive layer facing away from the first transparent substrate, the second cavity part is arranged on a surface of the second transparent conductive layer facing away from the first transparent substrate, a surface of the first cavity part facing away from the first transparent substrate is flush with a surface of the second cavity part facing away from the first transparent substrate, the second cavity part comprises at least one second through hole, the redistribution layer is arranged on the surfaces of the first cavity part and the second cavity part facing away from the first transparent substrate, and an orthographic projection of the at least one second through hole on the first transparent substrate is within an orthographic projection of the redistribution layer on the first transparent substrate.

5. The image sensor according to claim 4, wherein the packaging component further comprises an electrical connection part arranged in the second through hole and electrically connecting the second transparent conductive layer and the redistribution layer.

6. The image sensor according to claim 5, wherein a material of the electrical connection part is the same as a material of the redistribution layer.

7. The image sensor according to claim 3, wherein the solder mask face comprises a first mask part and a second mask part, wherein the first mask part is arranged on the surface of the first transparent conductive layer facing away from the first transparent substrate, and the second mask part is arranged on a surface of the cavity or the redistribution layer facing away from the first transparent substrate, a surface of the first mask part facing away from the first transparent substrate is flush with a surface of the second mask part facing away from the first transparent substrate, and the first mask part comprises at least one third through hole, and an orthographic projection of the at least one third through hole on the first transparent substrate is within an orthographic projection of the first transparent conductive layer on the first transparent substrate.

8. The image sensor according to claim 1, wherein the dimming component is arranged on a side of the first transparent substrate facing away from the packaging component.

9. The image sensor according to claim 8, wherein the dimming component comprises a first transparent conductive layer arranged on a surface of the first transparent substrate facing away from the photosensitive area of the sensor chip.

10. The image sensor according to claim 8, wherein the dimming component further comprises a second transparent substrate, and the second transparent substrate and the first transparent substrate are bonded and fixed by an optical transparent adhesive, and the first transparent conductive layer is arranged on a surface of the second transparent substrate facing away from the first transparent substrate.

11. The image sensor according to claim 2, wherein the dimming component further comprises:
an electrochromic layer arranged on a surface of the first transparent conductive layer facing away from the first transparent substrate;
an ion conductive layer arranged on a surface of the electrochromic layer facing away from the first transparent substrate;
an ion storage layer arranged on a surface of the ion conductive layer facing away from the first transparent substrate; and
a second transparent conductive layer arranged on a surface of the ion storage layer facing away from the first transparent substrate,
wherein orthographic projections of the electrochromic layer, the ion conductive layer, the ion storage layer and the second transparent conductive layer on the first transparent substrate are within an orthographic projection of the first transparent conductive layer on the first transparent substrate.

12. The image sensor according to claim 1, wherein the dimming component comprises a liquid crystal layer sandwiched between a third transparent substrate and a fourth transparent substrate.

13. The image sensor according to claim 12, wherein the dimming component further comprises:
a third transparent conductive layer arranged on a surface of the third transparent substrate facing the liquid crystal layer;
a first orientation layer arranged on a surface of the third transparent conductive layer facing the liquid crystal layer;
a first polarizer arranged on a surface of the third transparent substrate facing away from the liquid crystal layer;
a fourth transparent conductive layer arranged on a surface of the fourth transparent substrate facing the liquid crystal layer;
a second orientation layer arranged on the surface of the fourth transparent conductive layer facing the liquid crystal layer; and
a second polarizer arranged on a surface of the fourth transparent substrate facing away from the liquid crystal layer,
wherein a surface of the first polarizer facing away from the third transparent substrate and a surface of the first transparent substrate facing away from the packaging component are bonded and fixed by an optical transparent adhesive.

14. The image sensor according to claim 12, wherein the third transparent substrate and the fourth transparent substrate are thin glass substrates.

15. The image sensor according to claim 12, wherein the third transparent substrate and the fourth transparent substrate are flexible substrates.

16. The image sensor according to claim 12, wherein the dimming component further comprises:
a first nano-grating array arranged on a surface of the third transparent substrate facing the liquid crystal layer, the first nano-grating array comprising a plurality of nanowires extending in a first direction; and
a second nano-grating array arranged on a surface of the fourth transparent substrate facing the liquid crystal layer, the second nano-grating array comprising a plurality of nanowires extending in a second direction,
wherein the first direction is perpendicular to the second direction.

17. The image sensor according to claim 16, wherein the dimming component further comprises:
a fifth transparent conductive layer arranged a surface of the third transparent substrate facing the liquid crystal layer and filling gaps between a plurality of nanowires of the first nano-grating array;
a third orientation layer arranged on a surface of the fifth transparent conductive layer facing the liquid crystal layer;
a sixth transparent conductive layer arranged on a surface of the fourth transparent substrate facing the liquid crystal layer and filling gaps between a plurality of nanowires of the second nano-grating array; and
a fourth orientation layer arranged on a surface of the sixth transparent conductive layer facing the liquid crystal layer.

18. (canceled)

19. The image sensor according to claim 16, wherein the third transparent substrate and the first transparent substrate are the same transparent substrate.

20. (canceled)

21. (canceled)

22. A camera compact module, comprising the image sensor according to claim 1, and a lens module on a light incident side of the image sensor.

23. An electronic device comprising the camera compact module according to claim 22.

24. (canceled)
